(19) United States
(12) Patent Application Publication
(10) Pub. No.: US 2025/0355374 A1
(43) Pub. Date: Nov. 20, 2025

(54) SYSTEMS AND METHODS FOR VENTING A RETICLE POD

(71) Applicant: ENTEGRIS, INC., Billerica, MA (US)

(72) Inventor: Russ V. Raschke, Chanhassen, MN (US)

(21) Appl. No.: 19/207,185

(22) Filed: May 13, 2025

Related U.S. Application Data
(60) Provisional application No. 63/647,440, filed on May 14, 2024.

(51) Int. Cl. G03F 7/00

(52) U.S. Cl. CPC G03F 7/70933; G03F 7/70741; G03F 7/70841

(57) ABSTRACT

Described are methods and systems for venting a reticle pod held at an interior of a vacuum chamber while maintaining a higher pressure (or “positive” pressure) at the interior of the inner reticle pod relative to a pressure in the vacuum chamber interior and outside of the reticle pod.

### FIELD

This description relates to methods and systems for venting a reticle pod held in a vacuum chamber while maintaining a higher pressure at the reticle pod interior compared to a pressure in the vacuum chamber interior.

### BACKGROUND

Extreme ultraviolet lithography (also known as EUV or EUVL) is an optical lithography technology used in semiconductor device fabrication to make integrated circuits. The process uses extreme ultraviolet (EUV) wavelengths near 13.5 nanometers to produce a pattern by using a patterned photomask or “reticle” to expose a coating of photoresist solution placed on a substrate surface. Radiation is provided through or reflected off the patterned mask or reticle to form the image on the photoresist solution.

Extreme ultraviolet (EUV) lithography processing is performed in an evacuated atmosphere (a low pressure environment or a “vacuum” environment) to minimize energy loss of EUV light from atmospheric gases. The reticle must therefore be moved from a cleanroom environment having an ambient (atmospheric) pressure condition, into the evacuated environment of the lithography tool. Specialized devices referred to as “reticle pods” are used to contain reticles in a clean environment and to transfer reticles between a cleanroom environment and an evacuated environment of a lithography tool.

Some reticle pods include an inner reticle pod (“inner pod”) to hold and protect the reticle, and an outer reticle pod to contain and transport the inner pod and reticle. The inner pod can be removed from the outer pod to transfer the reticle between a cleanroom and an evacuated interior of a lithography tool. Common inner pod designs include a baseplate (or “base”) and a cover that together define an interior adapted to contain and protect the reticle. A perimeter of the base includes a flat sealing surface that engages a flat sealing surface at a perimeter of the cover to form a seal between the two sealing surfaces at their perimeters.

A reticle held within an inner reticle pod is transferred between a cleanroom environment and an evacuated processing space of a lithography tool through a “load lock” apparatus (or “load lock”). The load lock includes a chamber (“vacuum chamber” or “load lock chamber”) that connects the cleanroom to the lithography tool interior. The load lock functions as an airlock chamber to allow the inner reticle pod to be transferred from the ambient pressure environment of the cleanroom into the evacuated environment of the lithography tool by changing the pressure of the gaseous atmosphere within the inner pod during transfers.

Initially, with the inner pod located in the cleanroom environment, the inner pod interior contains air of the cleanroom environment at atmospheric pressure. To transfer the inner pod and reticle from the cleanroom into the interior of the lithography tool, the inner pod is placed into the load lock through a first (front) door connected to the cleanroom, with the load lock chamber being at the ambient pressure of the cleanroom. The first (front) door is then closed to form a gas-tight seal between the load lock chamber and the cleanroom. A second (rear) door between the load lock chamber and the interior of the lithography tool is also closed with a gas-tight seal. With both doors closed and sealed, the air atmosphere contained in the load lock chamber is evacuated, which also evacuates the interior of the inner reticle pod. The second door is then opened and the inner pod is moved into the lithography tool.

The sequence can be reversed to transfer the reticle from the lithography tool back into the cleanroom. With the load lock chamber evacuated, the reticle pod is moved through the second door from the lithography tool into the load lock chamber. The second door is then closed and the evacuated load lock chamber is “vented” by delivering air into the load lock chamber to reach atmospheric pressure within the load lock chamber and the inner reticle pod. The first door can then be opened and the inner reticle pod and reticle can be transferred into the cleanroom.

A function of the EUV inner pod is to protect the reticle contained in the inner pod from particle contamination during the transfer processes. The load lock uses mechanical assemblies such as valves and doors, which can include moving parts, lubricants, and sealing surfaces. Movement of these assemblies generates particle contaminants within the load lock chamber. As pressure inside of the load lock chamber changes during an evacuation or a venting step, the changing pressure disrupts the particles and causes the particles to move within the chamber interior. The reticle pod helps to prevent the particles from being deposited onto the reticle.

### SUMMARY

This description relates to methods and systems for venting a reticle pod held in a vacuum chamber while maintaining a higher pressure (or “positive” pressure) at the interior of the reticle pod relative to a pressure in the vacuum chamber interior that is exterior to the reticle pod.

According to common techniques for venting a reticle pod in a load lock chamber, venting gas is introduced into an open space (a.k.a. a bulk space) of a vacuum chamber; the “open space” or “bulk space” of a vacuum chamber interior refers to space at an interior of a vacuum chamber that is exterior to (outside of) the reticle pod, e.g., space between the sidewall, top, and bottom surfaces that define the vacuum chamber interior and the outside surfaces of a reticle pod contained within the vacuum chamber interior. Venting gas that is initially delivered to the open space of the vacuum chamber interior builds to a relatively higher (positive) pressure within the open space of the vacuum chamber relative to a lower pressure in the reticle pod interior. The venting gas delivered initially into the open space of the vacuum chamber interior only secondarily flows from the open space into the reticle pod interior, through an opening or seal in the reticle pod.

The reticle pod (e.g., an inner reticle pod of a multi-pod assembly) includes one or more openings, typically as part of a cover, designed to allow a gas to flow between the reticle pod exterior and the reticle pod interior during an evacuation or a venting step. Conventional venting steps operate with a higher venting gas pressure in the open space of the vacuum chamber interior compared to venting gas pressure within the reticle pod interior. Consequently, during a conventional venting step, venting gas flows through the opening from the open space of the vacuum chamber interior into the reticle pod interior. The reticle pod opening typically includes a filter to prevent particle contaminants from being carried into the reticle pod interior during a venting step.

The reticle pod also includes a seal at its perimeter formed by opposed sealing surfaces of the base and the cover. The seal does not completely prevent venting gas from flowing through the seal during an evacuation or a venting step. Consequently, during a conventional venting step, venting gas also flows through the seal from the open space of the vacuum chamber interior into the reticle pod interior.

Venting gas that flows through the seal can carry particle contaminants into the reticle pod interior through the seal. To prevent these particle contaminants from being carried into the reticle pod interior by the venting gas, a seal can be designed to allow only a small flow of venting gas into the reticle pod interior.

The seal and the filter of a reticle pod can also be designed to allow a desired balance of venting gas flows through the filter and through the seal. The amount of venting gas that passes through a filter or through a seal is referred to as “conductance.” A preferred ratio of flow through a reticle pod filter versus flow through a reticle pod seal (the “conductance ratio”) may be at least 50:50, 60:40, or 70:30.

Achieving a high conductance ratio requires a filter with a relatively high conductance and a seal with a relatively lower conductance (lower gas flow). A seal with a low conductance requires sealing surfaces that are extremely flat over the entire length of the seal. Example flatness values of reticle pod sealing surfaces are often less than 50 microns, e.g., less than 40 or 35 microns. Current inner reticle pods are sized to contain square reticles having both a length dimension and a width dimension of nominally 150 millimeters. The sealing surfaces extend along each side of the square reticle pod design, and each sealing surface is approximately 200 millimeters long to contain a 150 millimeter square reticle. Producing sealing surfaces of these lengths that also have such extremely flat surfaces is very challenging and adds significantly to the cost of the reticle pod.

Reticles having length dimensions greater than 150 millimeters would significantly improve semiconductor processing throughput. A barrier to using larger reticles is that a larger reticle requires a larger reticle pod, which would require extremely flat sealing surfaces of lengths that are greater than 200 millimeters, which would be very expensive using current reticle pod manufacturing techniques.

According to a feature of a venting method described herein, the identified methods are capable of effectively venting reticle pods that have less stringent flatness requirements of sealing surfaces; the methods allow effective venting of reticle pods that have sealing surfaces (of any useful length) with flatness values that can be higher than typically required, e.g., greater than 35, 40, 45, or 50 microns. Allowing for a less stringent flatness requirements of sealing surfaces allows for the use, particularly the venting of, reticle pods having longer sealing surfaces. Examples of reticle pod used according to the described methods can have longer sealing surfaces with flatness values that are achievable over the longer lengths, without a prohibitive cost increase.

More generally, methods as described perform a step of venting a reticle pod (of any size and having sealing surfaces of any flatness values) in a vacuum chamber while maintaining a higher venting gas pressure at the interior of the reticle pod compared to a venting gas pressure in an open space of the vacuum chamber interior. The pressure at the open space of the vacuum chamber interior refers to a pressure of venting gas in the space that is within the vacuum chamber interior but exterior to (outside of) the reticle pod. The venting step is performed by maintaining a positive pressure in the reticle pod interior relative to the pressure in the open space of the vacuum chamber interior.

According to common venting techniques, venting gas is directly introduced through a vent into the open space or bulk space of an evacuated vacuum chamber interior (e.g., evacuated load lock chamber interior) and flows only indirectly from the vacuum chamber interior into the reticle pod interior due to a positive pressure in the open space of the vacuum chamber interior relative to a pressure in the reticle pod. The reticle pod is initially evacuated and as the amount venting gas in the vacuum chamber interior increases, a portion of the venting gas initially introduced into the vacuum chamber interior flows under pressure into the reticle pod interior.

The venting gas that flows from the vacuum chamber interior into the reticle pod interior can carry particle contaminants present in the vacuum chamber interior into the reticle pod interior, thus contaminating the reticle. Additionally, particle contamination can be generated at the sealing surfaces between the cover and the base by friction that occurs with contact and movement between the sealing surfaces. This type of particle contamination can also be carried into the reticle pod interior by venting gas that is allowed to pass through the seal and into the reticle pod interior.

In contrast to previous venting techniques, venting steps as described maintain a positive pressure at an interior of a reticle pod. The positive pressure reduces or prevents the flow of venting gas through the seal from open space of the vacuum chamber interior into the reticle pod interior. The amount of particle contaminants that may potentially be carried by the venting gas into the reticle pod interior is reduced. Advantageously, the need for extremely flat sealing surfaces can be reduced. Positive pressure at the reticle pod interior allows a reticle pod to be effectively vented even with sealing surfaces of relatively high flatness values (e.g., greater than 35 microns), without allowing higher amounts of particle contaminants to pass through the seal into the reticle pod interior. Avoiding the need for stringently flat sealing surfaces allows for the use of seals having longer lengths, e.g., seals longer than 200 millimeters. The ability to use longer-length seals can in turn allow the use of larger reticle pods and larger reticles. Altogether, a venting method that maintains a positive pressure at a reticle pod interior reduces the risk of particle contaminants entering the reticle pod interior through a seal, during a venting step, without incurring the higher cost associated with very low flatness requirements for sealing surfaces of longer lengths.

In one aspect, the description relates to a method of venting a reticle pod. The reticle pod includes: a base having a base sealing surface; a cover having a cover sealing surface engaged with the base sealing surface to form a seal; a reticle pod interior between the base and the cover; and at least one opening in the reticle pod that allows fluid flow between the reticle pod interior and an exterior of the reticle pod. The method includes: with the reticle pod contained in an evacuated vacuum chamber interior, dispensing a flow of venting gas from a reticle pod vent to direct the flow of venting gas through the opening in the reticle pod and into the reticle pod interior; and maintaining a pressure of venting gas in the reticle pod interior that is higher than a pressure of venting gas in the vacuum chamber interior and outside of the reticle pod.

In another aspect, the disclosure relates to vacuum chambers. The vacuum chamber may include: a vacuum chamber interior, a front door, and a rear door; the front door being located between the vacuum chamber interior and a front space having an ambient pressure and being adapted to selectively open and close. The front door in an open position allows a reticle pod to be transferred between the vacuum chamber interior and the front space, and the front door in a closed position creates a gas-tight seal between the vacuum chamber interior and the front space. The rear door is located between the vacuum chamber interior and an evacuated interior and is adapted to selectively open and close. The rear door in an open position allows a reticle pod to be transferred between the vacuum chamber interior and the evacuated interior, and the rear door in a closed position creates a gas-tight seal between the vacuum chamber interior and the evacuated interior. The vacuum chamber also includes a reticle pod vent adapted to direct venting gas through an opening of a reticle pod that is supported in the vacuum chamber interior; and a control system adapted to maintain a positive pressure in the reticle pod interior relative to a pressure in the vacuum chamber interior and outside of the reticle pod.

In yet another aspect, the description relates to a method of venting a reticle pod that contains an evacuated interior and is contained in a vacuum chamber. The method includes directing a flow of venting gas into a reticle pod interior while maintaining a higher pressure of the venting gas in the reticle pod interior compared to a pressure of the venting gas in a vacuum chamber interior and outside of the reticle pod.

### BRIEF DESCRIPTION OF THE DRAWINGS

FIG. 1 shows an example of a reticle pod as described contained in a vacuum chamber connected to a front space and rear space.

FIGS. 2A through 2C show example steps of an evacuation process for evacuating a reticle pod contained in a vacuum chamber.

FIGS. 3A through 3C show example steps of an venting process as described for evacuating a reticle pod contained in a vacuum chamber.

All figures are schematic and not to scale.

### DETAILED DESCRIPTION

The description relates to methods and systems for venting a reticle pod contained in a vacuum chamber while maintaining a higher pressure (or “positive” pressure) at the interior of the reticle pod compared to a pressure in the vacuum chamber exterior to the reticle pod, i.e., in the open space outside of the reticle pod.

The described methods and systems can be useful with reticle pods that are known and currently used in the semiconductor processing industry, in combination with equipment that includes a vacuum chamber used for venting a reticle pod to transfer a reticle between a cleanroom or other environment that operates at ambient (atmospheric) pressure and an evacuated interior of a semiconductor processing device such as an EUV lithography device. Examples of reticle pod designs are described in U.S. Pat. Nos. 8,713,359 and 8,776,814, and in US patent publication 2023/0129336.

The reticle pod can include a lower portion or “base” that serves as a lower or bottom structure of the reticle pod, and an upper portion or “cover” that serves to cover the base and enclose a reticle supported by the base. The base and the cover together define a reticle pod interior that is adapted to contain, enclose, and protect a reticle. The base and the cover each have a perimeter and a sealing surface at the perimeter. When the base and the cover are assembled to contain an enclosed reticle, the base sealing surface contacts the cover sealing surface to form a seal between the cover sealing surface and the base sealing surface. The reticle pod also includes an opening that allows a gaseous fluid to flow between the reticle pod interior and an exterior of the reticle pod. The reticle pod opening can include a filter to prevent particle contaminants from entering the reticle pod interior with gas that passes from the reticle pod exterior, through the opening, and into the reticle pod interior.

Each of the base and the cover includes a sealing surface at a perimeter, referred to as a “base sealing surface” and a “cover sealing surface.” The sealing surfaces are formed to have a high degree of flatness, to form a substantially closed seal between the opposed sealing surfaces when the cover is placed over the base with the sealing surfaces in engaged contact. When the surfaces are in contact to form the seal, the seal is not perfectly tight and does not form a gas-impermeable seal. The amount of gas that flows through the seal will depend on the magnitude of the pressure differential that exists across the seal (between the reticle pod interior and an exterior side of the seal), and also on the strength of the seal, which is determined by the flatness of the base sealing surface and the flatness of the cover sealing surface.

The reticle pod can be an inner reticle pod that includes a cover and a base, of a type that known as an “inner reticle pod” (or “cassette”) of a dual containment pod that contains the first or inner pod within a second or outer pod, known as a reticle SMEF pod. The sealing surfaces may be polished or ultra planar metal surfaces.

Past reticle pod sealing surfaces pods are designed to have low flatness values, to reduce the amount of venting gas that passes through the seal during venting. This need for low flatness of the sealing surfaces restricts the length of the seal because forming a sealing surface with a low flatness becomes significantly more difficult and costly as the length of the sealing surface increases.

The seal has a length dimension that extends along the perimeter of the reticle pod. A reticle pod that has a square shape has a length alone each side of the square-shaped reticle. A typical length of some currently-commercial reticle pods that are vented with a positive pressure in the open space of a vacuum chamber interior is 200 millimeters, i.e., typical reticle pods have a square shape with 200 millimeter sides. For seals of this length, a common flatness value of the sealing surface is below 50 microns, e.g., less than 40 or 35 microns.

Venting methods as described, performed with a positive pressure at the reticle pod interior, reduce the amount of venting gas or prevent venting gas from passing through the seal and into the reticle pod interior. According to example methods, venting gas is directed into the reticle pod interior through an opening in the reticle pod to create a positive pressure at the reticle pod interior. The venting gas delivered to the reticle pod interior may flow from the reticle pod interior, through the seal, and then into the open space of the vacuum chamber interior.

Advantageously, maintaining a positive pressure at the reticle pod interior allows for a less stringent flatness requirement of the sealing surfaces. Venting methods as described may be used with reticle pods that have sealing surfaces having relatively higher flatness values, e.g., above 35 microns, e.g., in a range from 35, 40, 45, or 50, up to or greater than 100, 150, 200, or 300 microns.

Further, and advantageously, because the described methods can be performed with reticle pods having sealing surfaces of relatively higher flatness values, the lengths of the seals can be greater. Sealing surfaces having higher flatness values over longer lengths can be manufactured much more easily and at a comparatively lower cost compared to longer-length sealing surfaces with relatively lower flatness values (below 50, 45, 40, or 35 microns). For example, a venting method that uses a positive pressure at a reticle pod interior can be performed on reticle pods that have sealing surfaces with flatness values above 35 microns, e.g., in a range from 50 to 300 microns, allowing for seal lengths of greater than 200 millimeters, e.g., greater than 220 or 250 millimeters.

A positive pressure may be created and maintained at a reticle pod interior by any useful technique by delivering a useful amount and volume of venting gas into the reticle pod interior, within a vacuum chamber interior. According to certain example methods and vacuum chamber configurations, a positive pressure can be produced at the interior of the reticle pod by delivering a flow of venting gas directly into the reticle pod interior through an opening in the reticle pod (“reticle pod opening”).

According to example vacuum chambers and methods, the vacuum chamber can include a vent, referred to as a “reticle pod vent,” that is adapted to direct a flow of venting gas directly into an interior of a reticle pod that is contained in the vacuum chamber interior. The reticle pod vent can be connected to a source of venting gas at an exterior of the vacuum chamber. The reticle pod vent can be stationary or may be moveable within the vacuum chamber.

A reticle pod vent may optionally include a reticle pod nozzle at a delivery end of the reticle pod vent at a location within an interior of a vacuum chamber. A reticle pod nozzle may be a surface, device, or structure at a delivery end of reticle pod vent that delivers venting gas directly to an opening of a reticle pod. A reticle pod nozzle can be designed to engage a surface of the reticle pod near (e.g., at or adjacent to) an opening in the reticle pod to facilitate the delivery of venting gas flowing from the reticle pod vent to the reticle pod opening and reticle pod interior. Optionally, an engagement between a reticle pod surface and a reticle pod nozzle can include a conformable surface or a gasket that may produce a fluid-tight seal or a substantially fluid-tight seal between the nozzle and the reticle pod surface.

During a venting step, a reticle pod vent is positioned in a “venting position” relative to a reticle pod. A “venting position” of a reticle pod vent relative to reticle pod opening is a position of the reticle pod vent (and optional nozzle) relative to a position of the reticle pod opening at which a flow of venting gas from the reticle pod vent is directed into the reticle pod interior, through the reticle pod opening, at a rate and volume to produce and maintain a positive pressure at the reticle pod interior relative to a pressure in the vacuum chamber interior and outside of the reticle pod, i.e., a pressure in the open space of the reticle pod interior.

To position the reticle pod vent at a venting position relative to a reticle pod, the reticle pod vent may be either stationary or movable within the vacuum chamber interior. For example, a reticle pod vent may be stationary and located at a position in the vacuum chamber interior that will allow a reticle pod to be placed into the vacuum chamber at a position that causes the reticle pod vent to be at a venting position. In a specific example, a reticle pod vent may be positioned at a vacuum chamber interior at a bottom region of the vacuum chamber. The reticle pod vent is stationary and adapted to deliver a flow of venting gas in a vertically upward direction. A reticle pod can include a reticle pod opening at a bottom of the reticle pod, e.g., through the base. The reticle pod is transferred into the vacuum chamber and positioned with the reticle pod opening in the base being positioned above the reticle pod vent. During a venting step, the reticle pod vent delivers a flow of venting gas through the reticle pod opening in the base and directly into the reticle pod interior.

According to other systems and methods, the reticle pod vent can be moveable within the vacuum chamber interior between a venting position and a non-venting position. During use, a reticle pod that includes a reticle pod opening in a cover is transferred into the vacuum chamber. The reticle pod vent is initially positioned in a non-venting position. To perform a venting step, the reticle pod vent is moved from the non-venting position into a venting position that allows the reticle pod vent to direct venting gas through the reticle pod opening and into the reticle pod interior. With the reticle pod vent positioned in the venting position, the reticle pod vent delivers a flow of venting gas through the reticle pod opening in the cover. When the venting step is completed the reticle pod vent is returned to a non-venting position.

According to certain example methods and vacuum chambers, a vacuum chamber may include one or more additional vents, referred to as “vacuum chamber vents,” that are adapted to deliver one or more separate flows of venting gas into the vacuum chamber interior at a location different from the venting gas that is delivered through the reticle pod vent, e.g., the one or more vacuum chamber vents deliver venting gas into the open space of the vacuum chamber interior. Each of the one or more vacuum chamber vents can be connected to a source of venting gas at an exterior of the vacuum chamber.

A vacuum chamber adapted to perform a venting method as described can also be capable of performing an evacuation step to remove air at atmospheric pressure from the vacuum chamber interior. The vacuum chamber may include an evacuation port that is connected to a fluid pump that is capable of removing gaseous fluid (e.g., air) from the vacuum chamber interior to reduce the pressure at the interior to a pressure level that is comparable to a pressure present at an evacuated interior of a lithography tool, e.g., an EUV lithography tool. An evacuation port may be an opening or port that is used for the purpose evacuating the vacuum chamber interior during an evacuation step, and may not have an additional use or function. Optionally, a reticle pod vent or a vacuum chamber vent could also be useful as an evacuation port to remove air from a vacuum chamber interior during an evacuation step.

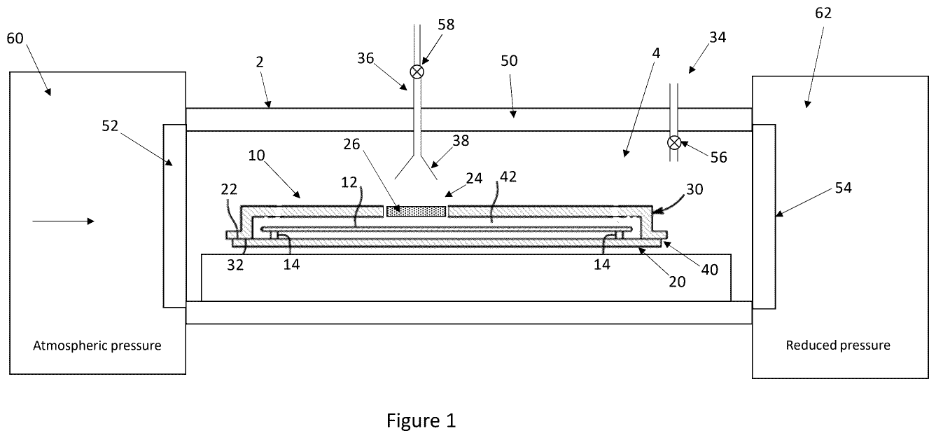

An example of a reticle pod that can be used with methods as described is shown at FIG. 1. Reticle pod 10, shown in cross-section, may be an inner pod of a multiple-pod reticle system that also includes an outer pod (not show). Reticle pod 10 includes base 20 and cover 30. Each of base 20 and cover 30 includes a perimeter. A flat upper surface at a perimeter of base 20 is sealing surface (“base sealing surface”) 22. A flat lower surface at a perimeter of cover 30 is sealing surface (“cover sealing surface”) 32. As illustrated at FIG. 1, cover 30 is resting on and supported by base 20, with base sealing surface 22 contacting cover sealing surface 32 to form seal 40. Cover 30 placed over base 20 defines reticle pod interior 42, which encloses reticle 12 supported by reticle pod supports 14. Reticle pod cover 30 includes reticle pod opening 24, which allows for gas to flow between reticle pod interior and an exterior of reticle pod 10. As illustrated, reticle pod opening includes filter 26.

As shown at FIG. 1, reticle pod 10 is contained in vacuum chamber interior 4 of vacuum chamber 2. A portion of the interior space of vacuum chamber interior 4 is taken up by the volume of reticle pod 10. The portion of the space of vacuum chamber interior 4 that is outside of the volume of reticle pod 10 is referred to as the “open” space or the “bulk” space of vacuum chamber interior 4.

Vacuum chamber 2 may, for example, be a load lock chamber situated between a “front space” 60 and rear space 62. Front space 60 and rear space 62 contain atmospheres having different pressures, and vacuum chamber 2 acts as an air lock that is adapted to perform evacuation and venting steps required to transfer a reticle pod with a reticle contained in the reticle pod between the two atmospheres. An example of a front space 60 may be an enclosed cleanroom environment containing cleanroom air at atmospheric pressure. An example of a rear space 62 may be a space having low pressure or “evacuated” interior, such as an evacuated interior of a lithography processing system.

Reticle vent 36 and reticle nozzle 38 may be used in a step of venting reticle pod 10 by delivering venting gas to vacuum chamber interior 4, particularly to reticle interior 42. Optional vacuum chamber vent 34 may be use in a venting step to deliver venting gas to the open space of vacuum chamber 4. Valve 58 controls a flow of venting gas between vacuum chamber interior 4 and a source of venting gas (not shown) or may be used to remove a gaseous atmosphere from vacuum chamber interior exterior 4 during an evacuation step. Valve 56 controls a flow of venting gas between vacuum chamber interior 4 and a source of venting gas (not shown) or may be used to remove a gaseous atmosphere from vacuum chamber interior exterior 4 during an evacuation step.

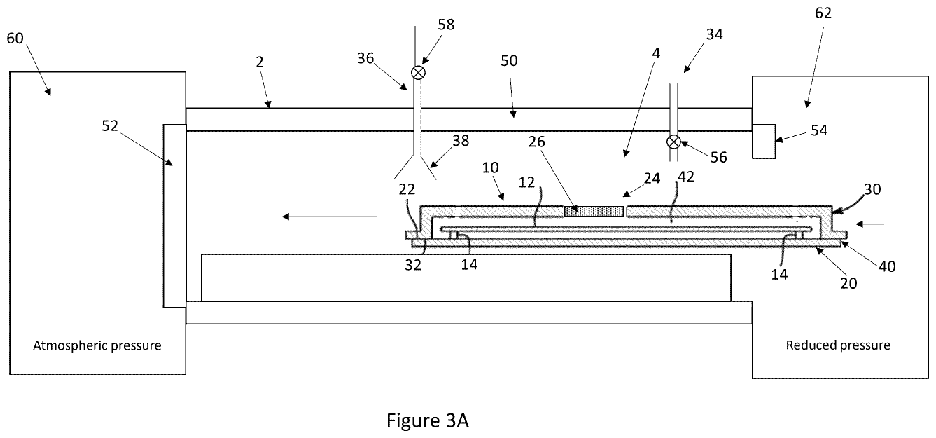

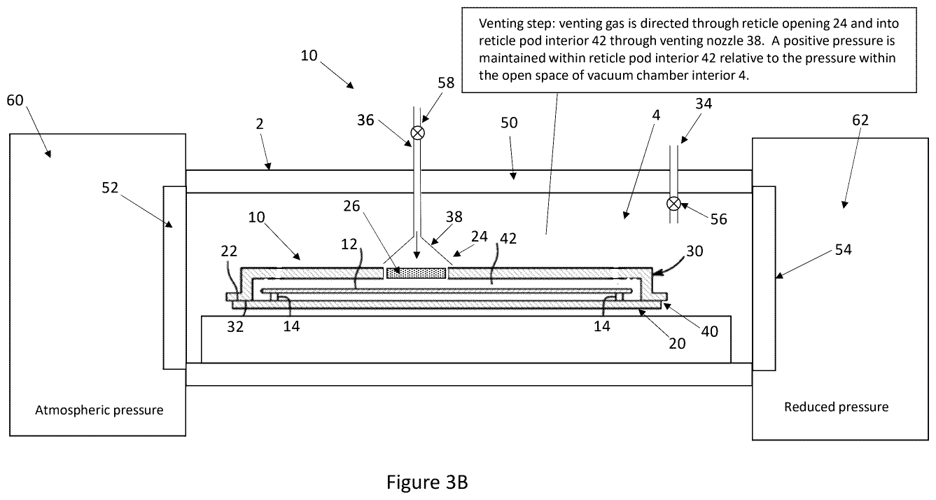

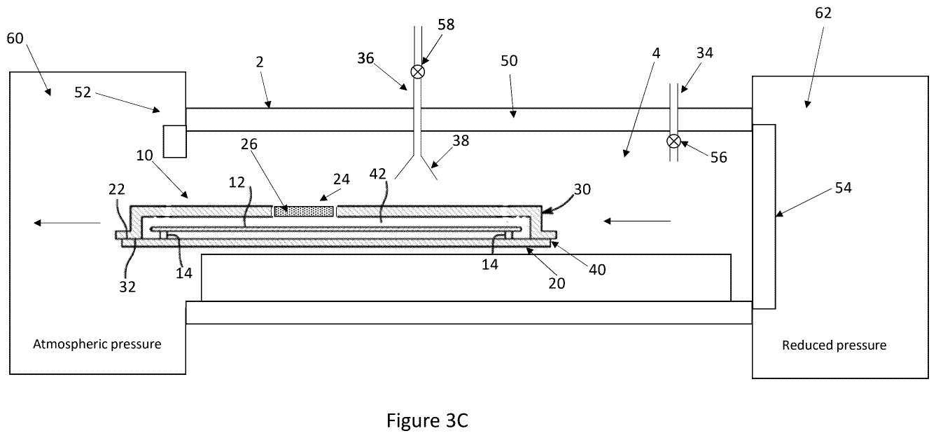

Vacuum chamber interior 4 is enclosed by a chamber body 50, front door 52, and rear door 54. Each door may be selectively opened and closed with a gas-tight seal. Vacuum chamber interior 4 is connected to a source of venting gas (not shown, e.g., air such as clean dry air (CDA)) by vent 36 that includes reticle pod nozzle 38. In the example of FIG. 1, reticle pod nozzle 38 is moveable (e.g., vertically) within vacuum chamber interior 4 and is adapted to be moved between a non-venting position at which nozzle 38 is situated away from reticle pod 10, and a venting position at which nozzle 38 is capable of delivering venting gas directly through reticle pod opening 24 into reticle pod interior 42. See FIG. 3B. Valve 58 controls a flow of venting gas through reticle pod vent 36 and a source of venting gas (not shown), or may be used to remove a gaseous atmosphere from vacuum chamber interior exterior 4. In a venting position, venting gas can be caused to flow through vent 36 and nozzle 38 to deliver a flow of venting gas directly into reticle interior 42 through reticle pod opening 24. Optionally, venting nozzle 38 forms an air-tight seal or a substantially air-tight seal with a surface of cover 30 at reticle pod opening 38. The air-tight seal may include a gasket between a surface of cover 30 and a surface of venting 38.

Example vacuum chamber 2 of FIG. 1 also shows an optional second vent 34, referred to as a vacuum chamber vent. Optional vacuum chamber vent 34 can be used to direct venting gas from a venting gas source (not shown) into vacuum chamber interior 4 at a location that does not direct the venting gas directly into reticle pod interior 42, i.e., to an open space within vacuum chamber interior 4 that is also at the exterior of reticle pod 10 contained in vacuum chamber interior 4. Optional chamber vent 34 may also be used in a step of evacuating vacuum chamber 4 by removing a gaseous atmosphere from vacuum chamber 4. Valve 56 control a flow of venting gas between vacuum chamber interior 4 and a source of venting gas (not shown).

In the figures, reticle pod opening 24 is shown to be included within cover 30 and to include filter 26. Reticle pod nozzle 38 is shown to be a moveable nozzle that can be lowered toward cover 30 to engage cover 30 to direct a flow of venting gas from nozzle 38 through cover opening 24 and directly into reticle pod interior 42. In alternate examples, reticle pod opening 24 may not include a filter. Also optionally, cover 30 may include one or more additional reticle pod openings (not shown), which may be filtered or un-filtered.

In yet other example system, a reticle pod opening 24 may additionally or alternately be included in base 20. A vent 36 and a reticle nozzle 38 may alternately or additionally be positioned within vacuum chamber 4 at a position below reticle pod 10 to allow the reticle pod nozzle 38 to engage a reticle pod opening 24 that is part of reticle base 20 from a location below reticle pod 10 and direct venting gas through the reticle pod opening in base 20. This alternate example of a reticle pod nozzle 38 may be movable or may alternately be fixed at a location at which the reticle pod opening in the base engages reticle pod nozzle 38 by positioning a reticle pod opening 24 of reticle pod 10 above reticle pod opening 24 during a venting step.

Vacuum chamber 2 includes a control system (not illustrated) that includes or is connected to one or more different types of sensors within or operatively connected to vacuum chamber 2, e.g., to control an evacuation step, a venting step, and movement of reticle pod 10 between a front space and a rear space. Sensors may include pressure, temperature, and gas flow sensors and sensors to move or detect a position of doors 52 and 54 and reticle pod 10. Controls may include controls to open and close doors 52 and 54, controls to open and close valves 56 and 58, controls to control an amount or rate of venting gas through vents 34 and 36, and controls of devices used to transfer a reticle pod between front space 60, vacuum chamber 50, and rear space 62. According to various example purification systems, a control system can include, as a computer processor, a microprocessor of any form, e.g., a process logic controller (PLC controller) embodied in an application-specific integrated circuit (ASIC), or the like.

To perform methods as described, the control system can be programmed to control a flow of venting gas into a reticle pod interior (e.g., through a reticle pod vent and optional reticle pod nozzle), while maintaining a positive pressure of the venting gas at the reticle pod interior. For example, in a vacuum chamber that includes both a reticle pod vent 36 and a vacuum chamber vent 34, a control system can be programmed to control the separate flows venting gas through reticle pod vent 36 and vacuum chamber vent 34 to produce and maintain a positive pressure at reticle pod interior 42 during a venting step. The control system may be adapted to deliver a flow rate (volume per time) of venting gas to the reticle pod interior that is greater than or that is less than the flow rate (volume per time) of venting gas delivered to the vacuum chamber interior outside of the reticle pod interior.

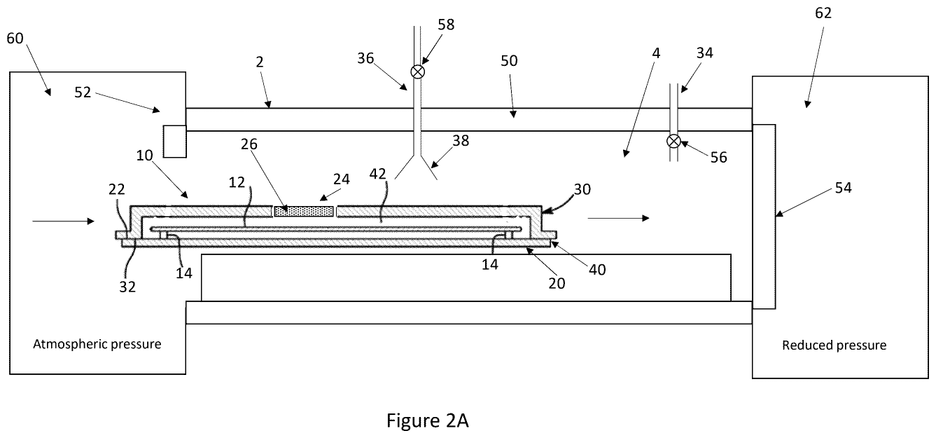

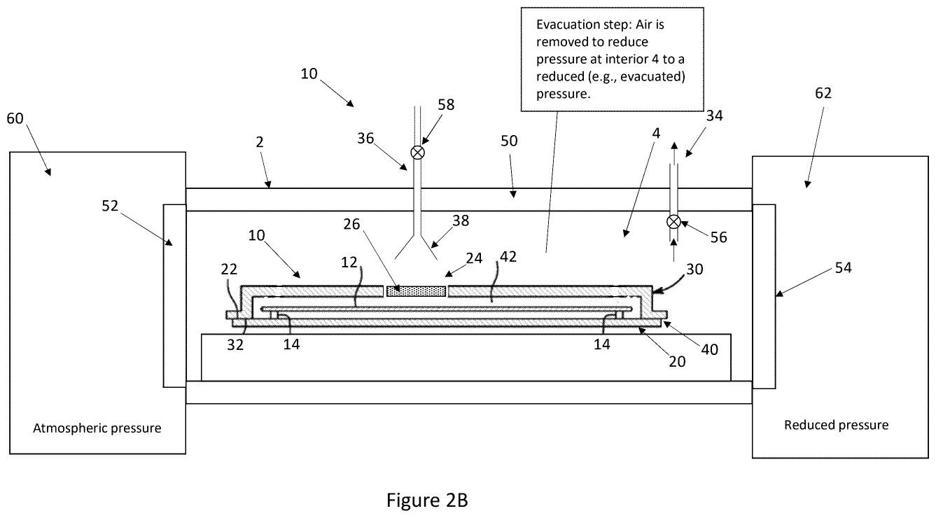

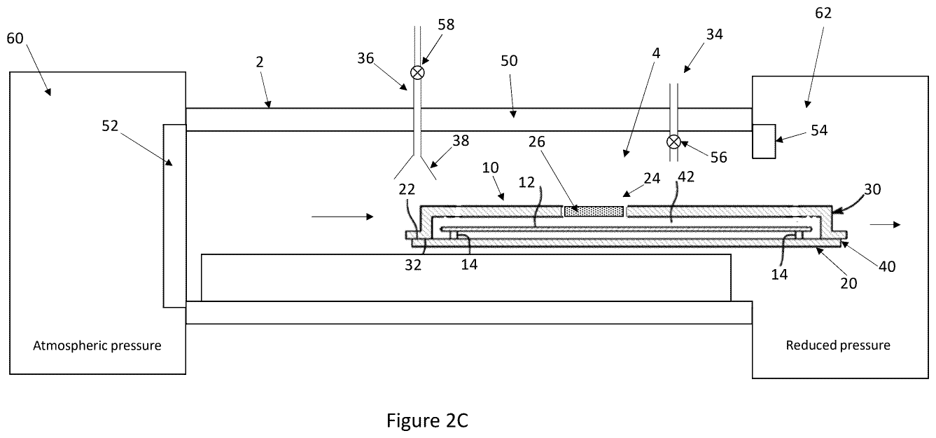

An example vacuum chamber such as vacuum chamber 2 of FIG. 1 may be used to transfer a reticle contained in a reticle pod from a front space (e.g., cleanroom) at one pressure condition into a rear space (e.g., evacuated interior of a lithography processing system) at a different pressure condition. Referring to FIG. 2A, reticle pod 10 that contains a reticle 12 is located in front space 60 (e.g., a cleanroom environment) at a first pressure, e.g., atmospheric pressure. Rear door 54 is closed and sealed between vacuum chamber interior 4 and rear space 62, having a second (e.g., reduced) pressure condition relative to front space 60. Valves 56 and 58 are closed. Door 52 between cleanroom environment 60 and vacuum chamber interior 4 is opened and vacuum chamber interior 4 is also at an atmospheric pressure condition. With door 52 open, reticle pod 10 is transferred into vacuum chamber interior 4 (see arrows).

As shown at FIG. 2B, front door 52 is then closed while rear door 54 remains closed. By an evacuation step, the air contained within vacuum chamber interior 4 is removed through an evacuation port (not shown), or optionally or alternatively through vent 34, vent 36, or both. The evacuation step is completed by removing air at interior 4 to create a reduced pressure comparable to a pressure of evacuated rear space 62.

As shown at FIG. 2C, with vacuum chamber interior 4 being evacuated, rear door 54 is opened to connect vacuum chamber 4 to the evacuated interior of rear space 62. Reticle pod 10 containing reticle pod 12 can be transferred into rear space 62, such as lithography processing system.

Example vacuum chamber 2 of FIG. 1 may also be used to transfer a reticle contained in a reticle pod from a rear space at one pressure condition (e.g., an evacuated pressure condition) to a front space (e.g., a cleanroom atmosphere) at a different pressure condition. Referring to FIG. 3A, reticle pod 10 is located in rear space 62 at a reduced pressure condition. Front door 52 is closed and sealed between vacuum chamber interior 4 and front space 60. Valves 56 and 58 are closed. Door 55 between rear space 62 and vacuum chamber interior 4 is opened and vacuum chamber interior 4 is also at a reduced (e.g., evacuated) pressure condition. With rear door 54 open, reticle pod 10 is transferred into vacuum chamber interior 4 (see arrows).

As shown at FIG. 3B, rear door 54 is then closed while front door 52 remains closed. To perform a venting step, reticle nozzle 38 is lowered from a non-venting position (shown at FIG. 3A) to a venting position at which reticle nozzle 38 is adjacent to reticle pod opening 24 of cover 30. Valve 58 is opened and venting gas is caused to flow through reticle nozzle 38, through reticle pod opening 24, and into reticle pod interior 42. Optionally, valve 56 may also be opened to cause venting gas to flow through vacuum chamber vent 38 and into reticle pod interior 42. During the venting step, the pressure of venting gas at reticle pod interior 42 remains at a higher level compared to the pressure of venting gas at the open space of vacuum chamber interior 4. Venting gas flows into reticle pod interior 42 and maintains a positive pressure within reticle pod interior 42 relative to the pressure at vacuum chamber interior 4, optionally causing venting gas to flow from reticle pod interior 42, through seal 40, and into the open space of vacuum chamber interior 4. The positive pressure prevents venting gas from flowing in the opposite direction, from the open space of vacuum chamber interior 4, through seal 40, and into reticle pod interior 4, thus preventing particle contaminants contained in vacuum chamber 4 from being carried by the venting gas into reticle chamber interior 42. A pressure differential between reticle pod interior 42 and the open space of vacuum chamber interior 4 may be of any magnitude that will prevent or reduce an amount of venting gas from flowing through seal 40 from vacuum chamber interior 4 into reticle pod interior 42 during the venting step.

The pressure within vacuum chamber 4 is brought to atmospheric pressure to match the atmospheric pressure condition in front space 60. Reticle pod nozzle 38 is retracted to a non-engaged position away from cover 30 (see FIG. 3C). The flows of venting gas through reticle pod nozzle 38 and through vacuum chamber vent 34 are terminated.

As shown at FIG. 3C, with vacuum chamber interior 4 being brought to atmospheric pressure, front door 52 is opened to connect vacuum chamber 4 to front space 60. Reticle pod 10 containing reticle pod 12 can be transferred into front space 60.

1. A method of venting a reticle pod,
the reticle pod comprising:
a base having a base sealing surface,
a cover having a cover sealing surface engaged with the base sealing surface to form a seal,
a reticle pod interior between the base and the cover,
at least one opening in the reticle pod that allows fluid flow between the reticle pod interior and an exterior of the reticle pod;
the method comprising:
with the reticle pod contained in an evacuated vacuum chamber interior, dispensing a flow of venting gas from a reticle pod vent to direct the flow of venting gas through the opening in the reticle pod and into the reticle pod interior, and
maintaining a pressure of venting gas in the reticle pod interior that is higher than a pressure of venting gas in the vacuum chamber interior and outside of the reticle pod.

2. The method of claim 1, wherein the higher pressure of venting gas in the reticle pod interior causes venting gas to flow from the reticle pod interior, through the seal, and into the vacuum chamber interior and outside of the reticle pod.

3. The method of claim 1, wherein each of the cover sealing surface and the base sealing surface has a flatness in a range of 10 to 300 microns.

4. The method of claim 3, wherein the seal has a length of at least 220 millimeters.

5. The method of claim 1, wherein each of the cover sealing surface and the base sealing surface has a flatness in a range of 50 to 300 microns and the seal has a length of at least 220 millimeters.

6. The method of claim 1, wherein the reticle pod vent is moveable within the vacuum chamber interior, the method comprising moving the reticle pod vent from a non-venting position to a venting position at which venting gas delivered from the reticle pod vent enters the reticle pod interior through the opening in reticle pod to produce a positive pressure at the reticle pod interior relative to a pressure at the vacuum chamber interior and outside of the reticle pod.

7. The method of claim 1, comprising delivering a second flow of venting gas from a vacuum chamber vent to the vacuum chamber interior and outside of the reticle pod.

8. The method of claim 7, comprising:
dispensing the flow of venting gas into the reticle pod interior at a first flow rate, and
dispensing the second flow of venting gas into the vacuum chamber interior at a second flow rate that is different from the first flow rate.

9. The method of claim 1, comprising:
transferring the reticle pod into the vacuum chamber interior from an EUV lithography tool interior with the vacuum chamber interior being evacuated, the EUV lithography tool interior being evacuated, and the reticle pod interior being evacuated,
forming a gas-tight seal between the vacuum chamber and the EUV lithography tool interior, then:
dispensing the flow of venting gas from the reticle pod vent through the opening in the reticle pod and into the reticle pod interior, and
maintaining the pressure of venting gas in the reticle pod interior above the pressure of venting gas in the vacuum chamber interior and outside of the reticle pod.

10. The method of claim 9, comprising delivering a second flow of venting gas through a vacuum chamber vent into the vacuum chamber interior and outside of the reticle pod.

11. A vacuum chamber comprising:
a vacuum chamber interior, a front door, and a rear door;
the front door being located between the vacuum chamber interior and a front space having an ambient pressure and being adapted to selectively open and close, wherein: the front door in an open position allows a reticle pod to be transferred between the vacuum chamber interior and the front space, and the front door in a closed position creates a gas-tight seal between the vacuum chamber interior and the front space;
the rear door being located between the vacuum chamber interior and an evacuated interior and being adapted to selectively open and close, wherein: the rear door in an open position allows a reticle pod to be transferred between the vacuum chamber interior and the evacuated interior, and the rear door in a closed position creates a gas-tight seal between the vacuum chamber interior and the evacuated interior;
a reticle pod vent adapted to direct venting gas through an opening of a reticle pod that is supported in the vacuum chamber interior; and
a control system adapted to maintain a positive pressure in the reticle pod interior relative to a pressure in the vacuum chamber interior and outside of the reticle pod.

12. The vacuum chamber of claim 11, comprising a vacuum chamber vent adapted to dispense a second flow of venting gas into the vacuum chamber interior and outside of the reticle pod.

13. The vacuum chamber of claim 11, wherein the reticle pod vent comprises a reticle pod nozzle comprising a surface that is adapted to contact a surface of the reticle pod at the opening in the reticle pod.

14. The vacuum chamber of claim 11, wherein the reticle pod vent is adapted to move within the vacuum chamber interior between a first position at which the reticle pod vent does not engage the reticle pod, and a second position at which the reticle pod vent engages the reticle pod at the reticle pod opening.

15. The vacuum chamber of claim 11, containing a reticle pod at the vacuum chamber interior.

16. The vacuum chamber of claim 15, wherein the reticle pod comprises:
a base having a base sealing surface,
a cover having a cover sealing surface engaged with the base sealing surface to form a seal,
a reticle pod interior between the base and the cover, and
at least one opening in the reticle pod that allows fluid to flow between the reticle pod interior and an exterior of the reticle pod.

17. The vacuum chamber of claim 16, wherein each of the cover sealing surface and the base sealing surface has a flatness in a range of 50 to 300 microns and the seal has a length of at least 220 millimeters.

18. A method of venting a reticle pod that contains an evacuated interior and is contained in a vacuum chamber, the method comprising directing a flow of venting gas into a reticle pod interior while maintaining a higher pressure of the venting gas in the reticle pod interior compared to a pressure of the venting gas in a vacuum chamber interior and outside of the reticle pod.

19. The method of claim 18, wherein the higher pressure of venting gas in the reticle pod interior causes venting gas to flow from the reticle pod interior, through a seal in the reticle pod, and into the vacuum chamber interior outside of the reticle pod.

20. The method of claim 18, wherein the reticle pod comprises:
a base having a base sealing surface,
a cover having a cover sealing surface engaged with the base sealing surface to form a seal,
a reticle pod interior between the base and the cover, and
at least one opening in the reticle pod that allows fluid to flow between the reticle pod interior and an exterior of the reticle pod.

21. The vacuum chamber of claim 20, wherein each of the cover sealing surface and the base sealing surface has a flatness in a range of 50 to 300 microns and the seal has a length of at least 220 millimeters.
